(19) United States
(12) Patent Application Publication
(10) Pub. No.: US 2025/0357160 A1
(43) Pub. Date: Nov. 20, 2025

(54) PLATFORM FOR IN-SPACE SERVICING, ASSEMBLY, AND MANUFACTURING OF ELECTRONICS AND THEIR HYBRID SYSTEMS

(71) Applicant: Purdue Research Foundation, West Lafayette, IN (US)

(72) Inventor: Ajay P. Malshe, West Lafayette, IN (US)

(73) Assignee: Purdue Research Foundation, West Lafayette, IN (US)

(21) Appl. No.: 19/211,454

(22) Filed: May 19, 2025

Related U.S. Application Data
(60) Provisional application No. 63/649,342, filed on May 18, 2024.

(51) Int. Cl. H01L 21/67; B22F 12/30; B22F 12/90; B33Y 10/00; B33Y 30/00; B33Y 80/00; H01L 21/66; H01L 21/687

(52) U.S. Cl. CPC H01L 21/67167; B22F 12/30; B22F 12/90; B33Y 10/00; B33Y 30/00; B33Y 80/00; H01L 21/67207; H01L 21/68707; H01L 22/10

(57) ABSTRACT

A semiconductor electronic and electrical hybrid manufacturing system for space operations includes a platform with a central hub surrounded by stations arranged in a pattern. The platform has multiple layers for distributing applications. Each station comprises multiple substations as a cluster tool for additive manufacturing, subtractive manufacturing, assembly, and testing of electronic and electrical components. A central robotic arm transfers components between the central hub and stations, while station-specific robotic arms move components between substations within each station. The system features integrated power distribution, data communication, and thermal management conduits connecting the central hub to each station. Standardized interfaces enable modular reconfiguration to adapt to different manufacturing requirements. A digital twin system provides remote monitoring and control capabilities through a virtual representation of the platform. The system operates in microgravity conditions with specialized equipment calibrated for space environments, enabling on-orbit servicing and repair of electronic components.

### CROSS REFERENCE TO RELATED APPLICATIONS

This application claims the benefit of U.S. Provisional Application No. 63/649,342 filed May 18, 2024, the entirety of which is hereby incorporated by reference.

### TECHNICAL FIELD

The present application relates to manufacturing platforms, and specifically to multi-station platforms for servicing, assembling, and manufacturing semiconductors and other electronic devices in outer space.

### BACKGROUND

The exploration of space for manufacturing purposes has garnered increasing interest due to the potential efficiencies it offers, particularly in the realm of producing devices tailored for space (and earth) applications and servicing existing spaceborne equipment. Space-based factories have the advantage of operating in a microgravity environment, enabling novel manufacturing processes that can result in more efficient production of devices designed specifically for space missions. Components manufactured in microgravity conditions may exhibit enhanced properties, such as improved structural integrity and performance, which are vital for the reliability and longevity of space systems. Moreover, the ability to produce and assemble these specialized devices in space reduces the need for costly and risky launches from Earth, streamlining logistics and minimizing the associated environmental impact. Additionally, space factories could play a crucial role in servicing and repairing existing satellites, spacecraft, and other space infrastructure. With the capability to manufacture replacement parts and conduct maintenance tasks in orbit, these facilities can extend the operational lifespan of space assets and mitigate the risks associated with hardware failures. Furthermore, by leveraging the vacuum environment of space, space-based factories can produce materials and components with exceptional purity and quality, leading to advancements in various scientific and industrial fields beyond space exploration. Overall, the efficiencies achieved through factories in space could revolutionize space technology and pave the way for new opportunities in exploration, communication, and scientific discovery.

### SUMMARY

Described herein is a factory-in-space (FiS) platform for space-based manufacturing. The platform includes multiple interconnected modules, each having multiple interconnected stations to facilitate the efficient production, servicing, and assembly of such electronics, including semiconductor manufacturing.

This summary is provided to introduce a selection of the concepts that are described in further detail in the detailed description and drawings contained herein. This summary is not intended to identify any primary or essential features of the claimed subject matter. Some or all of the described features may be present in the corresponding independent or dependent claims but should not be construed to be a limitation unless expressly recited in a particular claim. Each embodiment described herein does not necessarily address every object described herein, and each embodiment does not necessarily include each feature described. Other forms, embodiments, objects, advantages, benefits, features, and aspects of the present disclosure will become apparent to one of skill in the art from the detailed description and drawings contained herein. Moreover, the various apparatuses and methods described in this summary section, as well as elsewhere in this application, can be expressed as a large number of different combinations and subcombinations. All such useful, novel, and inventive combinations and subcombinations are contemplated herein, it being recognized that the explicit expression of each of these combinations is unnecessary.

### BRIEF DESCRIPTION OF THE DRAWINGS

While the specification concludes with claims which particularly point out and distinctly claim this technology, it is believed this technology will be better understood from the following description of certain examples taken in conjunction with the accompanying drawings, in which like reference numerals identify the same elements and in which:

FIG. 1 depicts a schematic diagram showing one exemplary factory-in-space (FiS) platform having a plurality of modules each having a plurality of stations; and

FIG. 2 depicts a photograph of a digital twin representation of the FiS of FIG. 1 being operated by one or more remote users.

The drawings are not intended to be limiting in any way, and it is contemplated that various embodiments of the technology may be carried out in a variety of other ways, including those not necessarily depicted in the drawings. The accompanying drawings incorporated in and forming a part of the specification illustrate several aspects of the present technology, and together with the description serve to explain the principles of the technology; it being understood, however, that this technology is not limited to the precise arrangements shown, or the precise experimental arrangements used to arrive at the various graphical results shown in the drawings.

### DETAILED DESCRIPTION OF THE ILLUSTRATED EMBODIMENTS

The following description of certain examples of the technology should not be used to limit its scope. Other examples, features, aspects, embodiments, and advantages of the technology will become apparent to those skilled in the art from the following description, which is by way of illustration, one of the best modes contemplated for carrying out the technology. As will be realized, the technology described herein is capable of other different and obvious aspects, all without departing from the technology. Accordingly, the drawings and descriptions should be regarded as illustrative in nature and not restrictive.

It is further understood that any one or more of the teachings, expressions, embodiments, examples, etc. described herein may be combined with any one or more of the other teachings, expressions, embodiments, examples, etc. that are described herein. The following described teachings, expressions, embodiments, examples, etc., should, therefore, not be viewed in isolation relative to each other. Various suitable ways in which the teachings herein may be combined will be readily apparent to those of ordinary skill in the art in view of the teachings herein. Such modifications and variations are intended to be included within the scope of the claims.

Heterogeneous semiconductor chips, and micro and nanodevices (herein referred to as “semiconductors”) are a backbone of most space operations and their resilience is determined by their electrical, electronic, and electromechanical components, interconnects, and systems (herein referred to as the “electronics system”). This is because of needs such as satellite communication, the Internet of Things (IoT), navigation and positioning systems, autonomous mobility and manipulation, imaging and sensing, power management, etc. This is further fueled by the growing demand for small satellites in space defense for cost reasons and functional versatility in space missions. Semiconductors provide processing power, memory support, high-rate data transfer, and energy management for minimized use, sensing, and actuation. Fast-approaching advanced demands are AI/ML in space, quantum computing and cryptography, nanosatellites and CubeSats, and interplanetary-internet and space-based networks, which are key for space security.

The factory-in-space (FiS) platform, which can also be referred to as a node or a distribution center, represents a pioneering endeavor in the realm of space-based manufacturing, integrating multiple interconnected modules each having multiple interconnected stations to facilitate the efficient production, servicing, and assembly of such electronics, including semiconductor manufacturing. Each station is designed to perform specific functions essential for the entire manufacturing process, from raw material processing to final product qualification.

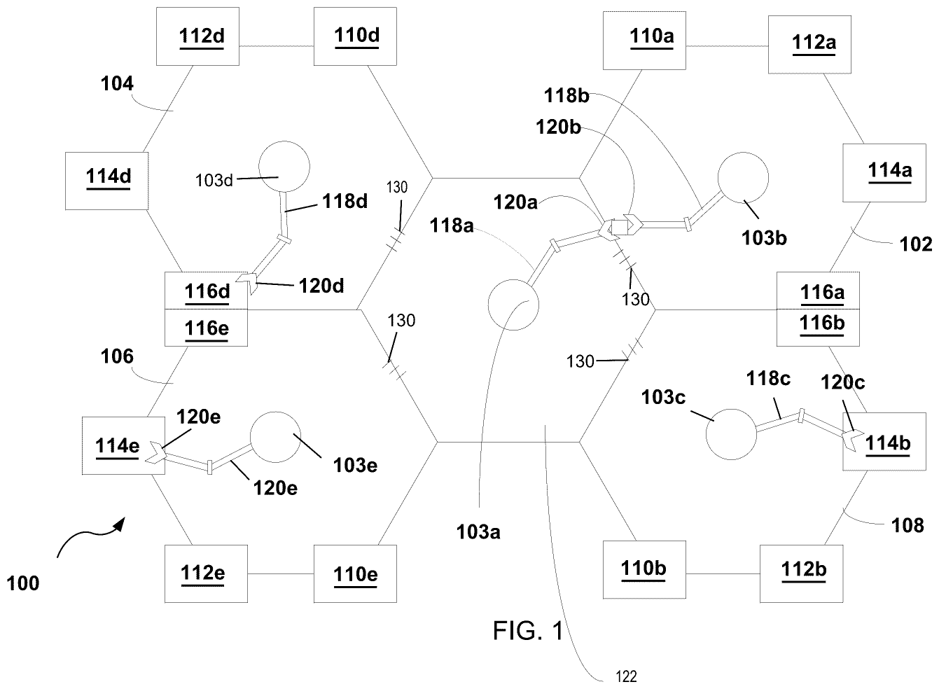

As shown in FIG. 1, FiS platform (100) comprises a plurality of stations (can also be referred to modules) arranged in a hexagonal pattern around a central hub, with the stations together forming a constellation configuration. The central hub comprises a primary station (122) positioned at the center of the constellation configuration. The platform 100 further comprises plurality of auxiliary stations (102, 104, 106, 108) positioned around the primary station (122), with each auxiliary station comprising a plurality of substations. Each auxiliary station (102, 104, 106, 108) includes substations (110a-c, 112a-e, 114a-e, 116a-c) to provide additive manufacturing (AM), subtractive manufacturing, micro-assembly, and measurement and qualification processes, respectively. The FiS platform (100) further includes interconnects (130) between the primary station (122) and each auxiliary station (102, 104, 106, 108). The interconnects (130) comprise conduits that provide pathways for power distribution, data communication, and thermal energy transfer between the stations. The power distribution pathways supply electrical energy from power sources to all components of the platform. The data communication pathways transmit control signals, sensor readings, and process information between stations. The thermal energy transfer pathways circulate cooling fluids or conduct heat to maintain operating temperatures across the platform.

Semiconductor samples are precision 3D manipulated within the FiS platform (100) and transferred across substations using robotic arms. The FiS platform (100) may also be configured for mobility between different locations in space to function as a point-of-service manufacturing system. In some embodiments, the platform (100) may incorporate propulsion systems to enable movement between orbital positions, enabling servicing of satellites or other space assets without requiring their retrieval or deorbit. In some embodiments, the platform (100) platform can be in orbit or on an extra-terrestrial surface, or both. The propulsion systems may comprise electric propulsion units mounted on the exterior of the primary station (122), with fuel storage compartments integrated within the hub structure. The propulsion control system may be configured to calculate optimal trajectories for rendezvous with target satellites, considering orbital mechanics and fuel efficiency parameters. Positioning sensors, including star trackers and inertial measurement units, may provide precise location and orientation data for navigation during transit between service points. Docking mechanisms or systems may be incorporated at designated connection points on the platform (100) to establish secure mechanical interfaces with client satellites during servicing operations, stabilizing the relative position between the manufacturing platform and the satellite being serviced. The mobile configuration enables the FiS platform (100) to deliver manufacturing capabilities directly to the point of need, significantly reducing the logistical complexity of space-based repair and maintenance operations.

The FiS platform (100) can be configured for specific repair and manufacturing operations addressing common failure modes in space systems. In some embodiments, the substations (110a-e, 112a-e, 114a-c, 116a-c) may include specialized equipment for repairing solar array damage caused by micrometeoroid impacts. This equipment may comprise precision imaging systems to identify fractured photovoltaic cells, laser ablation tools to remove damaged material, and material deposition systems to reconstruct the conductive grid patterns and semiconductor layers of the solar cells. The manufacturing processes may be tailored to handle the layered structure of solar cells, including transparent conductive oxides, semiconductor junctions, and metallic contact grids.

For focal plane array applications, the platform (100) may incorporate specialized handling equipment configured to process radiation-sensitive imaging sensors. This equipment may include radiation-shielded work areas within the substations, anti-static handling tools calibrated for the microgravity environment, and specialized test equipment for verifying the spectral response and noise characteristics of repaired imaging systems. The focal plane array processing capabilities may extend to various spectral ranges, including visible, infrared, and hyperspectral bands, with corresponding test equipment for each spectral domain. Microelectronic circuit repair operations may utilize microscale selective deposition of conductive materials to reconstruct fractured circuit traces, with real-time electrical testing to verify connectivity after repair. In these specific applications, the manufacturing process flow may be optimized for the particular materials and structures involved, with predefined robotic movements and tooling configurations stored in control system for rapid deployment when specific repair scenarios are identified.

The FiS platform (100) also implements comprehensive customization capabilities across all stations to accommodate diverse manufacturing requirements for different space missions. In some embodiments, each auxiliary station (102, 104, 106, 108) may be reconfigured through modular equipment inserts that can be exchanged or modified to support different processing techniques. These modular equipment inserts may connect to standardized mechanical, power, and data interfaces within each substation, enabling the integration of new manufacturing technologies without redesigning the entire platform structure. The primary station (122) may function as a configuration hub where replacement substation modules or tooling components are stored until needed, with the central robotic arm (118a) performing the exchange of equipment modules as required by specific manufacturing tasks. The customization system may incorporate a digital configuration database that stores technical specifications and operational parameters for each possible substation configuration, enabling rapid transition between different manufacturing profiles. For critical repair missions, the platform (100) may load specialized tooling packages tailored to the specific satellite or equipment being serviced, transitioning from general manufacturing capabilities to mission-specific configurations within a single orbital period. This reconfiguration capability extends to both hardware components and software control systems, with processing algorithms automatically adjusting to the installed equipment configuration.

The FiS platform (100) may also be configured for expansion through the incorporation of additional stations and substations, enabling scaling of manufacturing capacity and capabilities as operational requirements evolve. In some embodiments, the hexagonal architecture of the platform (100) may include standardized connection interfaces at external faces of the constellation, allowing for the attachment of additional auxiliary stations without requiring substantial reconfiguration of the existing structure.

Each new auxiliary station may connect to the existing structure through the same mechanical connectors, power distribution lines, data communication channels, and thermal conduits used in the initial configuration, ensuring compatibility and operational integration. A central control system may automatically recognize newly attached stations and incorporate them into the operational workflow, updating robotic movement paths and manufacturing sequence patterns to utilize the expanded capabilities.

New auxiliary stations may replicate the substation architecture of existing stations, with first, second, third, and fourth substations providing additive manufacturing, subtractive manufacturing, assembly, and testing capabilities, respectively. Alternatively, specialized auxiliary stations may be attached to provide unique manufacturing capabilities not present in the initial configuration, such as advanced materials processing, specialized radiation hardening, or expanded testing capabilities. The robotic control system may be configured to accommodate the expanded operational envelope, with robotic arm reach and motion planning algorithms adjusting to incorporate the additional transfer pathways. Through this modular expansion capability, the FiS platform (100) may evolve from a basic manufacturing node into a comprehensive space-based industrial facility capable of addressing increasingly complex manufacturing challenges.

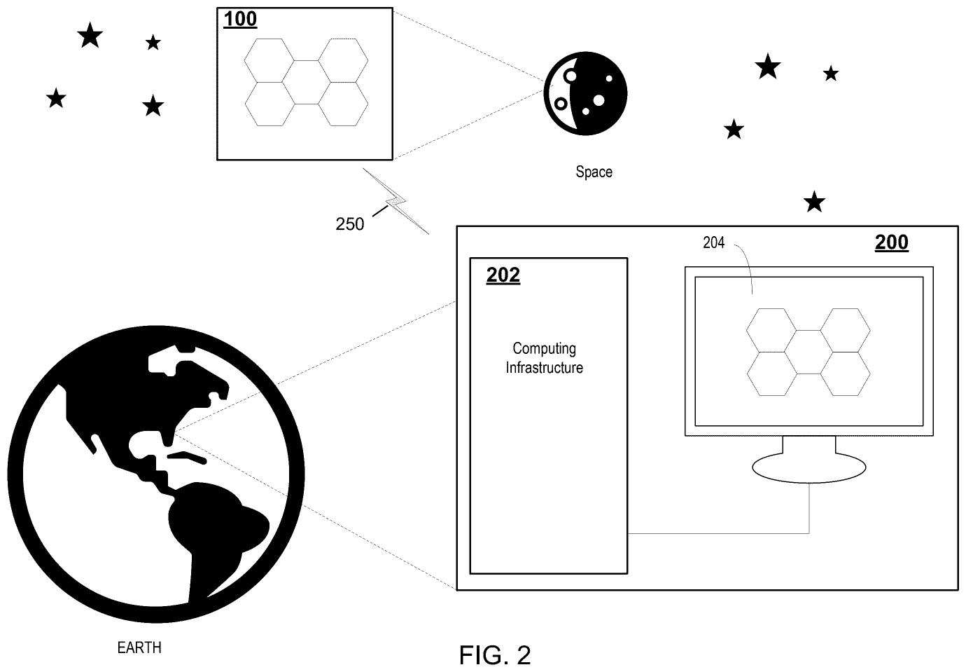

The customization architecture of the FiS platform (100) may support mission-specific configuration profiles that can be activated as complete systems. In some embodiments, these configuration profiles may define coordinated setups across multiple stations to create integrated manufacturing workflows optimized for particular applications. For example, for semiconductor processing, a configuration profile may configure the first substations (110a-e) with photolithography equipment, the second substations (112a-c) with etching systems, the third substations (114a-c) with diffusion capabilities, and the fourth substations (116a-c) with electrical characterization tools. For solar array repair, an alternative configuration may equip the first substations (110a-c) with transparent conductive oxide deposition systems, the second substations (112a-c) with laser cutting tools, the third substations (114a-c) with cell interconnect welding equipment, and the fourth substations (116a-c) with photovoltaic performance analyzers. The platform (100) may store multiple configuration profiles in its control system, enabling rapid transitions between different manufacturing capabilities in response to evolving mission requirements. Digital twin system (200) (shown in FIG. 2 and discussed in subsequent figure) may incorporate a configuration planning module that simulates different equipment layouts and workflow patterns, enabling operators to optimize station configurations before implementing physical changes to the platform (100). This advanced customization capability transforms the FiS platform (100) from a fixed manufacturing system into an adaptable production environment that can evolve to address emerging technical challenges throughout its operational lifetime.

The primary station (122) includes a robotic base (103a) supporting a central robotic arm (118a) with a manipulator (120a). The central robotic arm (118a) extends from the primary station (122) to reach each auxiliary station, transferring semiconductor components between the primary station and the auxiliary stations. Each auxiliary station includes a corresponding robotic base (103b, 103c, 103d, 103e) supporting respective robotic arms (118b, 118c, 118d, 118c) with manipulators (120b, 120c, 120d, 120e). The robotic bases (103a, 103b, 103c, 103d, 103c) serve as structural foundations and rotational mechanisms for the robotic arms within the platform. Each robotic base comprises a cylindrical housing that comprises motors, power distribution components, and control electronics for operating the attached robotic arm. The cylindrical housing is anchored to its respective station through structural supports that distribute mechanical loads and dampen vibrations. The upper portion of each robotic base incorporates a rotational bearing assembly that enables the robotic arm to rotate 360 degrees around the vertical axis as well as move the robotic arm freely upwards and downwards.

The primary station robotic base (103a) is positioned at a geometric center of the FiS platform (100), providing the central robotic arm (118a) with equidistant access to all auxiliary stations. The auxiliary station robotic bases (103b, 103c, 103d, 103e) are positioned at the interior edge of each auxiliary station, facilitating efficient transfer of materials between substations. Each robotic base contains power distribution modules that regulate electrical power for the robotic arm, data processing units that execute motion control algorithms, and thermal management systems that maintain operational temperatures for the electronic components. These station robotic arms transfer semiconductor components between substations within each auxiliary station, enabling materials to proceed through sequential manufacturing processes without manual intervention.

The hexagonal arrangement of stations is configured to optimize the reach efficiency of the robotic arms while minimizing the overall footprint of the platform. This provides capability in picking and choosing mission-specific functional materials, process applications, and servicing, assembly, and manufacturing capabilities. The physical dimensions and specifications of the primary station (122) and auxiliary stations (102, 104, 106, 108) may vary based on the specific manufacturing requirements and deployment constraints. In some embodiments, the primary station (122) each auxiliary stations (102, 104, 106, 108) may have specific dimensions while providing sufficient internal volume for the enclosed substations and associated equipment.

Central robotic arm manipulator (118a) and station robotic arm manipulators (118b, 118c, 118d, 118c) may comprise robotic systems with specific technical capabilities suited to their respective functions. The central robotic arm manipulators (118a) features a robotic arm enabled for comprehensive spatial positioning and orientation of materials within the FiS platform (100). This configuration enables the central robotic arm manipulator (118a) to reach any point within the operational volume of any auxiliary station with appropriate orientation for the required manufacturing task. The auxiliary station robotic arms (118b, 118c, 118d, 118c) are configured for localized operations within their respective auxiliary stations, transferring semiconductor components between adjacent substations during the manufacturing process.

The precision capabilities of the robotic arm manipulators are suited to the scale of semiconductor manufacturing. In some embodiments, the central robotic arm manipulator (118a) may achieve positioning accuracy of approximately 10-50 micrometers, enabling the precise handling of semiconductor components and materials. In some embodiments, that station robotic arm manipulators (118b, 118c, 118d, 118c) maintain similar positioning accuracy within their more confined operational ranges, ensuring precise material transfers between substations. In some embodiments, each robotic arm incorporates position feedback sensors, including optical encoders at each joint and end-effector position sensors, that provide real-time location data to the control systems.

The load capacities of the manipulators may vary based on their specific functions. In some embodiments, the central robotic arm manipulator (118a) may be configured to handle components with masses ranging from a few grams to several hundred grams, which encompasses typical semiconductor components and subassemblies. In some embodiments, station manipulators (120b, 120c, 120d, 120c) may have a higher load capacity to transfer completed assemblies or material batches between substations. Each manipulator (120a, 120b, 120c, 120d, 120c) may comprise an end-effector with interchangeable gripping mechanisms specifically configured for handling semiconductor components of various shapes and sizes. These gripping mechanisms utilize adjustable pressure sensors to apply sufficient force to secure components without causing damage to delicate semiconductor materials. The manipulators include rotational joints that enable reorientation of components during transfer operations, facilitating precise alignment for subsequent manufacturing processes.

The central robotic arm (118a) and station robotic arms (118b-118e) operate in a coordinated manner to ensure efficient material flow through the manufacturing process. When a component requires transfer from one auxiliary station to another, the station robotic arm at the originating station moves the component to a transfer position within reach of the central robotic arm (118a). The central robotic arm (118a) then retrieves the component and moves it to the vicinity of the destination station, where the receiving station robotic arm takes the component and moves it to the appropriate substation. This handoff process requires precise spatial and temporal coordination between the arms, facilitated by a centralized control system that tracks the position and status of all arms and schedules movements to prevent collisions. In some embodiments, the robotic arms maintain a predetermined spatial hierarchy, with the central robotic arm (118a) having movement priority in shared spaces, while station robotic arms yield when necessary. The coordination system incorporates both pre-planned movement patterns for routine transfers and dynamic path planning for non-standard operations, ensuring efficient material flow while maintaining operational safety.

The auxiliary stations (102, 104, 106, 108) may be connected through standardized interfaces or interconnects (130) that enable mechanical attachment, power distribution, and data exchange. In some embodiments, these connection mechanisms may utilize mechanical connectors that utilize robotic fastening systems that can be operated autonomously or under remote control, enabling for reconfiguration or expansion of the FiS platform (100) after deployment. The interconnects (130) may incorporate sealing elements to maintain pressure integrity when needed and electrical contacts for power and data transmission between stations. The mechanical connectors comprise interlocking components that create secure connections between adjacent stations, maintaining the structural integrity of the overall platform. These connections can be engaged or disengaged by the robotic arms, enabling modular reconfiguration of the platform to accommodate different manufacturing requirements. In some embodiments, the mechanical connectors include alignment guides that ensure precise positioning during connection operations, hermetic sealing elements that prevent atmosphere leakage in pressurized sections, and shock absorption features that dampen vibrations during operation.

The interconnects (130) between stations serve multiple functions beyond structural connection. The interconnects (130) comprise elongated conduits with internal channels for power, data, and thermal transfer. The power distribution lines within the interconnects (130) transmit electrical energy throughout the platform 100, supplying power to all stations and substations and their equipment. These power lines comprise high-efficiency conductors with redundant pathways to ensure continuous operation in case of localized damage. The data communication lines within the interconnects (130) may comprise of optical fiber and electrical signal pathways that carry control commands, sensor data, and process information between stations. These communication pathways enable coordinated operation of all manufacturing processes across the platform. The thermal conduits within the interconnects (130) regulate temperature across the platform by transferring heat between stations. These thermal conduits contain fluid circulation systems or solid-state thermal conductors that move heat from heat-generating processes to radiators or heat sinks, maintaining optimal temperature ranges for semiconductor manufacturing processes. The interconnects (130) are configured with external protective sheathing that shields the internal components from micrometeoroid impacts, radiation exposure, and thermal extremes encountered in the space environment.

The power distribution system within the FiS platform (100) may supply the electrical energy required by each module and station through a network of power buses and local power management units. In some embodiments, the power may be generated by external solar arrays, power systems, or other space-qualified power sources, with energy storage components to maintain operations during eclipse periods or peak power demands. The power generation system for the FiS platform (100) may utilize multiple sources to ensure sufficient energy availability across different operational scenarios. In some embodiments, the primary power generation may be provided by deployable solar arrays mounted on the primary station (122), featuring high-efficiency photovoltaic cells configured to generate electrical power when exposed to sunlight. These arrays may be articulated to optimize their orientation relative to the sun during orbital operations. Secondary power sources may include rechargeable battery modules distributed throughout the platform (100), providing energy storage capacity for operations during eclipse periods or when solar orientation is suboptimal. The battery modules may comprise lithium-ion or other space-qualified energy storage technologies with radiation tolerance and extended cycle life characteristics.

Power management systems may regulate the distribution of energy between stations, implementing load balancing algorithms to prioritize critical manufacturing processes when power constraints exist. In some embodiments, additional fuel cells or radioisotope power sources may supplement the primary power systems during extended operations away from optimal solar exposure, ensuring continuous manufacturing capability regardless of orbital position or orientation. The power systems may be configured with redundant pathways and isolation capabilities, enabling the platform to isolate electrical faults without compromising overall functional integrity.

Environmental control systems within the auxiliary stations (102, 104, 106, 108) may regulate internal conditions to protect sensitive equipment and materials. In some embodiments, these systems may include thermal management components to dissipate waste heat from manufacturing processes, particulate filtration to prevent contamination, and, where applicable, atmosphere management for processes requiring specific gas compositions or pressures.

Referring now to the substations, the first substation (110a-e) of the auxiliary stations (102, 104, 106, 108) may be dedicated to additive manufacturing and may serve as the initial stage of production where raw materials are transformed into precise components using additive techniques such as 3D printing. This station incorporates additive manufacturing technologies optimized for operation in microgravity conditions, ensuring the production of high-quality and complex semiconductor structures with exceptional precision and consistency. Advanced materials, including semiconducting compounds and conductive polymers, are utilized to create intricate semiconductor components tailored to the specific requirements of space-based electronics. Processes can be used for depositing, removing and shaping interconnected, manipulating chips, and assembling semiconducting boards with chips.

More particularly, the first substations (110a-e) includes semiconductor and electronics systems manufacturing equipment. The manufacturing platform technology may be a hybrid additive manufacturing platform (“hybrid-AM” or also referred to as “3D printing”). The hybrid-AM platform for semiconductors and related electronics is designed to combine 3D printing of a variety of electrically and thermally active, and passive materials such as metals or carbon (e.g., graphene), or ceramic-doped/filled polymers to form devices such as transistors, capacitors, resistors, and electrical interconnects (having, e.g., resolution at the micron scale). Part of hybridization is also because of the combination of direct 3D printing with the micro-assembly ability of heterogeneous COTS chips including high power efficiency, radiation, and high-temperature resistant wide-bandgap GaN and SiC-based FETs and HEMTs. A convergent manufacturing design is utilized for multi-material, multi-process hybrid AM, with dry filament, particles, sheet, or tape feeds with localized laser micro-welding abilities suitable for micro-gravity and vacuum space conditions where paste for 3D printing presents various physical issues.

A hybrid AM process platform provides advanced overall manufacturing design and materials versatility to customize an electronic system, readiness at the PON for example to repair satellites, and reliability at the same time reducing mass, manufacturing response time, cost, and waste, and conducting this all-in-one manufacturing FiS station. The hybrid-AM platform may also comprise material extrusion nozzles to deposit semiconductor materials in precise patterns according to digital design files. These nozzles comprise heating elements that bring materials to optimal extrusion temperature and precision apertures that control the diameter of extruded material. The electrical trace patterning equipment forms conductive pathways on semiconductor substrates by directing energy beams to cure conductive materials in specific patterns. This equipment includes focusing optics and beam deflection systems that achieve micron-scale resolution for creating circuit pathways. The hybrid-AM techniques implemented at the first substations (110a-e) may operate under specific parameters adjusted for microgravity conditions. In some embodiments, these parameters may include extreme temperature ranges between approximately −50° C. and 200° C., depending on the materials being processed, and vacuum pressure levels typically encountered in space environments. The precision requirements for space manufacturing may be at the micron scale, enabling the fabrication of intricate semiconductor structures with high dimensional accuracy.

Material behavior in microgravity environments differs from terrestrial conditions, particularly regarding fluid dynamics, heat transfer, and solidification processes. In some embodiments, the hybrid-AM platform at the first substations (110a-c) may incorporate sensors and feedback control systems to monitor and adjust for these differences during manufacturing operations. For example, the absence of convection-driven heat transfer in microgravity may have modified heating and cooling strategies to ensure proper material deposition and curing, while the reduced influence of gravity on fluid behavior may cause alternative approaches to material extrusion and positioning. As such, the first substations (110a-c) includes the ability to print two separate semiconductor functional materials for electrical and thermal applications applied on a PCB as well as ceramic substrates and the ability for micro-disassembly and assembly of COTS chips with i/o interconnects.

The first substations (110a-e) may be configured to process specific semiconductor and conductive materials selected for their performance characteristics in space environments. In some embodiments, these materials may include indium tin oxide (ITO) for transparent conductive applications, selected for its combination of electrical conductivity and optical transparency in sensor applications. Metallic conductors processed by the platform (100) may include copper (Cu) for high-conductivity signal pathways, silver (Ag) for low-resistance power distribution networks, and chromium (Cr) for adhesion layers and corrosion-resistant coatings. These metallic materials may be supplied in solid form and processed through direct energy deposition techniques, wherein focused energy sources precisely melt the materials in controlled patterns. Dielectric materials may include silicon dioxide (SiO₂) and silicon nitride (SiN) for insulation and passivation layers, deposited using plasma-enhanced processes within sealed chambers of the first substations (110a-c). For radiation-hardened applications, the material processing systems may incorporate specialized dopants or compound semiconductors, including gallium nitride (GaN) and silicon carbide (SiC) for wide-bandgap electronic components resistant to ionizing radiation effects. The material processing parameters, including deposition temperatures, energy densities, and cooling rates, may be specifically calibrated for the microgravity environment, compensating for the absence of convective heat transfer and gravitational effects on molten material behavior. The first substations (110a-c) may maintain material supplies in specialized containment systems that prevent cross-contamination between different material types while ensuring precise delivery quantities for each manufacturing operation.

The harsh launch and operational environment in space with extreme temperature variation, radiation, and vacuum applies stricter demand on the qualification of hybrid-AM semiconductors and electronics systems for USSF/AFRL. Therefore, the first substations (110a-c) includes advanced application and diagnostic abilities for functions such as radiation-hardening, anti-tamper, advanced thermal management, and more. These qualifications are applicable to electronics systems including active device chips, interconnects, passive devices, carrier boards/laminates, and thermos-mechanical frameworks.

Following additive manufacturing via the first substations (110a-e), the second substations (112a-c) is dedicated to subtractive manufacturing processes, where excess material is removed, and final shapes are refined to achieve the desired specifications. Utilizing precision machining techniques such as milling and etching, this station enables the precise shaping and finishing of semiconductor components, ensuring optimal performance and reliability in space environments. Automated machining systems equipped with high-resolution imaging and sensing capabilities ensure the accuracy and integrity of the manufacturing process, even in the absence of gravitational forces. In some embodiments, these substations comprise precision laser ablation systems equipped with beam focusing optics capable of micron-scale material removal without generating significant debris. The laser ablation systems may utilize wavelength-selective lasers optimized for specific materials, including semiconductors, metals, and dielectric compounds, enabling the selective removal of damaged components without affecting adjacent structures. The second substations (112a-e) may also incorporate precision milling equipment with multi-axis control for mechanical material removal when required for thicker structures or specialized geometries. These milling systems may utilize diamond-tipped or ceramic cutting tools resistant to wear in the space environment, with integrated vision systems providing real-time feedback for dimensional accuracy. Etching systems within the second substations (112a-e) may enable chemical or plasma-assisted material removal for precise semiconductor feature creation, with closed-loop material recovery systems to capture and contain etchant chemicals and removed materials. The subtractive manufacturing processes are calibrated for microgravity operation, with specialized containment systems preventing the dispersal of removed material particles within the space environment. Temperature control systems may regulate the thermal conditions during cutting operations to prevent heat-induced damage to adjacent semiconductor structures, with integrated cooling capabilities that function without convective heat transfer.

Once the individual semiconductor components are fabricated and refined, they are transferred to the third substation (114a-c) (by the robotic arms), which comprise semiconductor assembly equipment for micro-assembly and transformation processes. The third substations (114a-e) can include precision component placement devices that position integrated circuit components with micrometer accuracy using vacuum pickup tools and multi-axis positioning systems calibrated for microgravity operation. The placement systems may incorporate machine vision technologies that identify component orientation and alignment features, enabling accurate positioning even with variable component geometries.

Advanced soldering equipment within the third substations (114a-c) may utilize directed energy techniques, including laser soldering and electron beam soldering, to create precise electrical connections without conventional convection-dependent heating methods. These soldering systems may implement closed-loop thermal monitoring to prevent overheating of sensitive semiconductor components, with real-time temperature mapping across the entire assembly. The third substations (114a-e) may also incorporate specialized radiation hardening equipment that applies protective coatings to assembled electronic components, enhancing their resistance to ionizing radiation through conformal passivation layers or specialized semiconductor treatments. Wire bonding equipment may create interconnections between semiconductor dies and package substrates using ultrasonic bonding techniques adapted for space conditions. Encapsulation systems may apply protective polymers or hermetic sealing techniques to shield completed assemblies from the space environment, with materials selected for outgassing compliance and radiation stability. The third substations (114a-c) may also incorporate advanced transformation capabilities, including surface modification technologies that can alter the physical, electrical, or optical properties of manufactured components to achieve specific performance characteristics.

Following the third substations (114a-e), the fourth substations (116a-e) are dedicated to measurements and qualification, where the manufactured semiconductor devices undergo comprehensive testing and validation to ensure compliance with the stringent performance specifications and quality standards required for space applications. In some embodiments, these substations (116a-e) comprise advanced analytical instrumentation specifically calibrated for the unique constraints of space manufacturing. The spectroscopic analysis equipment may include X-ray fluorescence spectrometers for non-destructive elemental composition verification, spectroscopy for molecular structure characterization, and infrared spectroscopy for identifying chemical bonding configurations in manufactured components. High-resolution microscopy systems may incorporate scanning electron microscopy with energy-dispersive X-ray analysis capabilities for nanoscale feature inspection and elemental mapping across component surfaces. Optical microscopy with digital image processing may enable automated defect detection according to predefined quality parameters.

Electrical testing equipment within the fourth substations (116a-e) may conduct comprehensive performance characterization across multiple operational parameters, including current-voltage characteristics, frequency response, and noise behavior. These tests may be performed across simulated space environment conditions, including temperature cycling between thermal extremes and exposure to simulated radiation. Environmental testing capabilities may include thermal vacuum chambers that reproduce the combined effects of vacuum and temperature variations on component performance. Mechanical testing equipment may evaluate the structural integrity of assembled components through vibration analysis and mechanical shock resistance testing. The qualification processes implemented in the fourth substations (116a-e) may adhere to standardized space hardware qualification protocols, generating comprehensive certification documentation for all manufactured components. Data collection systems may compile test results into standardized formats compatible with space mission assurance requirements, enabling traceability throughout the component lifecycle. The integrated testing approach verifies both individual component performance and system-level functionality before deployment in critical space applications.

Thus, this enables, in one example, a fleet of vehicles working in concert in orbit (and/or extra-terrestrial surfaces) to achieve a variety of tasks, including inspection, maintenance, repair, and assembly. While targeted at dynamic shielding applications, this capability has constructive applications in modular manufacturing and could be reconfigurable.

As shown in FIG. 2, a remote, customizable digital twin (200) is communicatively coupled with the FiS platform (100) via wireless communication for use by remote users. The virtual 3D representation of the physical asset FiS platform (100) may be captured, for example, using COTS Liberty Reach 3D scanning technologies. High-definition CAD software Catia may be used for creating a 3D model with sub-millimeter precision, or when a less detailed model is acceptable, mesh-based 3D modeling software such as Blender will be used. This digital platform includes a set of tools and services to support the creation, visualization, and analysis of mission-specific digital twins and allow the visual components to reflect the gathered sensor data. This digital platform (200) includes predictive algorithms and machine learning capabilities to assist with predicting the future state of the asset.

The digital twin system (200) establishes a connection between Earth and the space-based FiS platform (100) through a wireless communication link (250). The wireless communication link (250) transfers data bidirectionally between the FiS platform (100) in space and an Earth-based computing infrastructure (202). In some embodiments, the wireless communication link (250) comprises radio frequency transmitters and receivers operating across S-band, X-band, or different band frequencies. In some embodiments, the wireless communication link (250) may utilize optical laser communication systems for higher data throughput. In some embodiments, the wireless communication link (250) may employ quantum communication protocols for secure data transmission. This link transmits telemetry data, control commands, and system states between the FiS platform (100) and the computing infrastructure (202), providing the necessary connectivity for platform monitoring and control.

The computing infrastructure (202) may include at least one processor, a memory, a communication system, a user interface, a display, and various data processing modules. One or more of the components of the computing infrastructure (202) may be located within a central control facility or could be separated into multiple different locations for redundancy and operational flexibility.

The processor may be configured to execute various programmed operations or instructions stored in a memory device such as a device or circuitry operating in accordance with software or otherwise embodied in hardware or a combination of hardware and software (e.g., a processor operating under software control or the processor embodied as an application specific integrated circuit (ASIC) or field programmable gate array (FPGA) specifically configured to perform the operations described herein, or a combination thereof) thereby configuring the device or circuitry to perform the corresponding functions as described herein. In this regard, the processor may be configured to analyze electrical signals communicated thereto to provide or receive manufacturing data from the FiS platform (100) and additional data from other sources. For example, the processor may be configured to receive telemetry data from the platform sensors and process this information.

The computing infrastructure (202) may also include computing hardware for executing the predictive algorithms and machine learning capabilities. In some embodiments, the computing hardware may comprise one or more processors configured to execute software instructions stored in memory components. The processors may include general-purpose central processing units (CPUs), graphics processing units (GPUs), or specialized machine learning accelerators suited for executing complex simulation algorithms. The memory components may include both memory for active processing and memory for long-term storage of the virtual 3D representation, simulation data, and machine learning models.

In some embodiments, the computing hardware may be distributed across multiple locations, with some components positioned on Earth in control centers and others potentially integrated within the FiS platform (100) itself. The Earth-based components may be implemented on high-performance computing clusters capable of processing large amounts of simulation data, while space-based components may utilize radiation-hardened computing systems configured to withstand the space environment.

In some embodiments, the processor may be further configured to implement signal processing and simulation algorithms. The processor may be configured to perform enhancement features to improve the display characteristics of platform data or images, collect or process additional data, such as temperature readings, radiation levels, material flow rates, or others, or may filter extraneous data to better analyze the collected information. The processor may further implement notices and alarms, such as those determined or adjusted by a user, to reflect manufacturing anomalies, component failures, material depletion, or excess radiation levels.

In some embodiments, the memory includes one or more non-transitory storage or memory devices such as, for example, volatile and/or non-volatile memory that may be either fixed or removable. The memory may be configured to store instructions, computer program code, manufacturing process data, and additional data such as material specifications, component designs, and historical performance metrics in a non-transitory computer readable medium for use, such as by the processor for enabling the computing infrastructure (202) to carry out various functions in accordance with example embodiments of the present invention. For example, the memory may be configured to buffer input data for processing by the processor. Additionally or alternatively, the memory may be configured to store instructions for execution by the processor.

The communication system may be configured to enable communication to the FiS platform (100) and configured to retrieve data from various external data sources. Additionally, the communication interface may be configured to communicate with other space-based manufacturing platforms, allowing the digital twin system (200) to send and receive information regarding manufacturing processes, component designs, or other relevant data as needed. The communications interface may include one or more communications modules configured to communicate with one another in any of a number of different manners including, for example, via a network. In this regard, the communications interface may include any of a number of different communication backbones or frameworks including but not limited to, for example, Ethernet, satellite communication protocols, cellular, Wi-Fi, or other suitable networks.

The communication system may also comprise a user interface comprising, for example, a keyboard, keypad, function keys, mouse, scrolling device, input/output ports, touch screen, or any other mechanism by which an operator may interface with the system. Through the user interface, operators can input commands to control the FiS platform (100), adjust manufacturing parameters, initiate emergency procedures, or perform routine maintenance operations.

The digital twin can be displayed on a screen (204) of the computing infrastructure (202) providing a comprehensive visual representation of the FiS platform (100), enabling operators to monitor and control manufacturing operations without direct physical access to the space-based system. This display (204) shows all aspects of the FiS platform (100), including the structural configuration, the status of all manufacturing processes, the positions and movements of robotic arms, the flow of materials through the system, and the environmental conditions within each station. The digital twin display (204) updates continuously based on telemetry data received from the FiS platform (100), ensuring that operators have access to current information for decision-making and control. In some embodiments, the display (204) may also incorporate predictive visualizations that simulate the future states of the FiS platform (100) based on current conditions and planned operations, enabling operators to anticipate potential issues before they occur. The display (204) (e.g., one or more screens) may be configured to present images of the digital twin (200) and may include or otherwise be in communication with a user interface configured to receive input from operators. The display (204) may be, for example, a conventional LCD (liquid crystal display), a touch screen display, or any other suitable display known in the art upon which images may be displayed. In some embodiments, the display (204) may present multiple sets of data (or images generated from multiple sets of data). Such data includes platform structural visualizations, manufacturing process status, material flow diagrams, component temperature readings, radiation levels, robotic arm positions, or any other type of information relevant to the FiS platform (100) operations.

The digital twin system (200) may incorporate human-in-the-loop operational capabilities to combine computational precision with human decision-making for complex manufacturing tasks. In some embodiments, the human interaction system may comprise haptic feedback controllers that transmit the physical state of manipulated components to human operators through force-feedback mechanisms, enabling precise control of delicate assembly operations. In some embodiments, the visual interface may incorporate stereoscopic displays providing depth perception for three-dimensional manipulation tasks, with augmented reality overlays highlighting critical features or Control inputs from human operators may be filtered through motion smoothing algorithms that compensate for communication latency and operator hand tremor while preserving intentional movements. The control system may implement a supervisory structure wherein routine operations proceed autonomously, with the system pausing to request human input when encountering unrecognized conditions or when decision points require contextual judgment. This supervisory structure may include pre-programmed decision thresholds that determine which operations can proceed automatically and which require human authorization. Human operators may interact with the system through multiple modalities, including physical controllers, gesture recognition systems, or voice commands, with the input method selected based on the precision requirements of the specific manufacturing task. The human-in-the-loop system may incorporate a training mode wherein the platform (100) records human operator actions during complex procedures, enabling the extraction of procedural knowledge for future autonomous operations. This approach combines the adaptability of human problem-solving with the precision and endurance of robotic systems, particularly valuable for complex repair scenarios where predetermined procedures may be insufficient.

The communication system between the digital twin (200) and the FiS platform (100) may utilize various protocols to ensure reliable data exchange. In some embodiments, the communication system may employ space-qualified communication standards compatible with existing satellite communication networks or dedicated links. The communication infrastructure may support both telemetry data and high-bandwidth transmissions for transferring detailed manufacturing data, visual feeds, and control commands.

In some embodiments, the communication system may incorporate latency handling mechanisms configured to accommodate the signal delay between Earth and the FiS platform (100). These mechanisms may include predictive modeling to anticipate platform states during communication gaps, local decision-making capabilities on the FiS platform (100) for time-sensitive operations, and automated synchronization procedures to reconcile the digital twin representation with the actual platform state once communication is reestablished.

The communication system may also incorporate redundancy features to maintain operational capability in case of primary system failure. In some embodiments, these redundancy features may include multiple communication pathways operating on different frequencies, backup transmitters and receivers, and store-and-forward capabilities to preserve data integrity during temporary communication disruptions. Security measures for the communication and control systems may include encryption protocols, authentication mechanisms, and intrusion detection systems designed to protect against unauthorized access or interference with manufacturing operations.

Reference systems that may be used herein can refer generally to various directions (for example, upper, lower, forward and rearward), which are merely offered to assist the reader in understanding the various embodiments of the disclosure and are not to be interpreted as limiting. Other reference systems may be used to describe various embodiments, such as those where directions are referenced to the portions of the device, for example, toward or away from a particular element, or in relations to the structure generally (for example, inwardly or outwardly).

While examples, one or more representative embodiments and specific forms of the disclosure have been illustrated and described in detail in the drawings and foregoing description, the same is to be considered as illustrative and not restrictive or limiting. The description of particular features in one embodiment does not imply that those particular features are necessarily limited to that one embodiment. Some or all of the features of one embodiment can be used in combination with some or all of the features of other embodiments as would be understood by one of ordinary skill in the art, whether or not explicitly described as such. One or more exemplary embodiments have been shown and described, and all changes and modifications that come within the spirit of the disclosure are desired to be protected.

That which is claimed:

1. An electronics manufacturing system for space operations, comprising:
a platform comprising:
a central hub; and
a plurality of stations positioned around the central hub, wherein each station of the plurality of stations comprises:
a first substation comprising semiconductor additive manufacturing equipment;
a second substation comprising semiconductor subtractive manufacturing equipment;
a third substation comprising semiconductor assembly equipment; and
a fourth substation comprising semiconductor testing equipment;
a central robotic arm positioned within the central hub and configured to transfer semiconductor components between the central hub and the plurality of stations; and
station robotic arms positioned at each station of the plurality of stations and configured to transfer semiconductor components between each substation.

2. The electronics manufacturing system of claim 1, wherein the first substation comprises a hybrid additive manufacturing platform configured to combine 3D printing of materials with assembly of integrated circuit components.

3. The electronics manufacturing system of claim 2, wherein the hybrid additive manufacturing platform is configured to process multi-materials comprising semiconductors, metals, and dielectrics.

4. The electronics manufacturing system of claim 2, wherein the hybrid additive manufacturing platform comprises dry filament or tape feeds with localized laser micro-welding abilities.

5. The electronics manufacturing system of claim 1, wherein the second substation comprises milling equipment and etching equipment for removing material from semiconductor components.

6. The electronics manufacturing system of claim 1, wherein the third substation comprises component placement devices and soldering equipment for placing, attaching, and interconnecting semiconductor electronic and electrical components onto circuit boards.

7. The electronics manufacturing system of claim 6, wherein the third substation comprises radiation hardening equipment.

8. The electronics manufacturing system of claim 1, wherein the fourth substation comprises analytical instruments comprising at least one of: spectroscopy, microscopy, and electrical testing equipment to assess structural, chemical, and electrical properties of the semiconductor devices.

9. The electronics manufacturing system of claim 1, further comprising a digital twin system comprising remote-based monitoring station; and a communication link between the remote-based monitoring station and the platform.

10. The electronics manufacturing system of claim 9, wherein the remote-based monitoring station comprises display screens for visualizing a virtual representation of the platform.

11. The electronics manufacturing system of claim 10, wherein the remote-based monitoring station comprises at least one processor and memory storing instructions that, when executed by the at least one processor, cause the at least one processor to generate the virtual representation of the platform; monitor operations of the platform; and remotely control operations of the platform.

12. The electronics manufacturing system of claim 1, wherein the platform comprises propulsion system configured to enable movement between orbital positions, wherein the propulsion system comprises positioning sensors for navigation, and docking mechanisms configured to establish secure mechanical interfaces with satellites for servicing operations.

13. The electronics manufacturing system of claim 1, wherein the platform comprises power distribution lines and data communication lines connecting the central hub to each station of the plurality of stations.

14. The electronics manufacturing system of claim 1, wherein the central robotic arms and the station robotic arms comprises articulating joints providing multiple degrees of freedom of movement.

15. The electronics manufacturing system of claim 1, wherein each station of the plurality of stations connects to adjacent stations through mechanical connectors.

16. The electronics manufacturing system of claim 1, wherein the first substation comprises material extrusion nozzles and electrical trace patterning equipment for depositing conductive pathways onto semiconductor substrates.

17. The electronics manufacturing system of claim 1, wherein each station of the plurality of stations comprises environmental control systems configured to regulate internal conditions of each station of the plurality of stations.

18. A method for manufacturing semiconductor and electronics components in space comprising, a central hub and a plurality of stations positioned around the central hub, wherein each station of the plurality of stations comprises a plurality substation, wherein the method comprises:
depositing semiconductor materials through additive manufacturing equipment at first substations of the plurality substations;
removing excess semiconductor material through subtractive manufacturing equipment at second substations of the plurality substations;
assembling semiconductor components through assembly equipment at third substations of the plurality substations;
testing assembled semiconductor components through testing equipment at fourth substations of the plurality substation;
transporting semiconductor components between a central hub and the plurality of stations, wherein a central robotic arm transports the semiconductor components; and
transporting semiconductor components between the plurality of substations within each station of the plurality of stations, wherein a station robotic arm transports the semiconductor components.

19. The method of claim 18, further comprising a digital twin system comprising remote-based monitoring station; and a communication link between the remote-based monitoring station and the platform.

20. A mobile factory system for in-space electronic device manufacturing, comprising:
a platform comprising a central hub and a plurality of manufacturing stations positioned around the central hub;
a propulsion system configured to position the platform in proximity to space assets requiring servicing;
a docking mechanism configured to establish secure mechanical interface with the space assets;
a central robotic arm positioned within the central hub and configured to transfer semiconductor components between the central hub and the plurality of manufacturing stations;
a station robotic arm positioned at each manufacturing station of the plurality of manufacturing stations and configured to transfer the semiconductor components within each respective manufacturing station; and
a digital twin system communicatively coupled with the platform for remote monitoring and control of the platform.
